(19) United States
(12) Patent Application Publication
(10) Pub. No.: US 2009/0215259 A1
(43) Pub. Date: Aug. 27, 2009

(54) SEMICONDUCTOR PACKAGE AND METHOD OF MANUFACTURING THE SAME

(75) Inventors: Kye Nam LEE, Yongin-Si (KR); Young Jin PARK, Seongnam-Si (KR); Hyun Kyu YANG, Yeongi-Gun (KR); Yoo Ran KIM, Gongju-Si (KR)

Correspondence Address: HORIZON IP PTE LTD, 7500A Beach Road, #04-306/308 The Plaza, SINGAPORE 199591, SG

(73) Assignees: Young Jin PARK, Seongnam-Si (KR); PETARI INCORPORATION, Daejeon (KR)

(21) Appl. No.: 12/417,644

(22) Filed: Apr. 3, 2009

Related U.S. Application Data
(62) Division of application No. 11/768,919, filed on Jun. 27, 2007.

(30) Foreign Application Priority Data
Jun. 27, 2006 (KR) 10-2006-0058028

(51) Int. Cl. H01L 21/768

(52) U.S. Cl. 438/614; 257/E21.589

(57) ABSTRACT

Disclosed is a semiconductor package and a method of manufacturing the same. The semiconductor package includes a semiconductor chip that includes metal pads provided on a predetermined area of an upper side of a semiconductor substrate, where element structures used to manufacture a semiconductor element are formed, and bump electrodes connected to the metal pads; and a passivation film that is provided on an entire surface of the semiconductor chip other than upper surface of the bump electrodes. Therefore, it is possible to avoid difficulties in performing an epoxy underfill process used in a conventional flip chip bonding, and complexity and high cost resulting from the use of a molding compound process and a solder ball process. It is also possible to prevent damages to the lateral surface of the semiconductor chip due to an absence of the passivation film on the lateral surface of the semiconductor chip in a conventional wafer level package.

### CROSS REFERENCE TO RELATED APPLICATIONS

This application is a Divisional application which claims benefit of co-pending U.S. patent application Ser. No. 11/768,919, filed on Jun. 27, 2007, which claims priority from Korean Patent Application No. 10-2006-0058028 filed on Jun. 27, 2006 in the Korean Intellectual Property Office, which are hereby incorporated by reference in their entirety.

### BACKGROUND OF THE INVENTION

1. Field of the Invention

The present invention relates to a semiconductor package and a method of manufacturing the same and, more particularly, to a semiconductor package where a passivation film is provided on an entire semiconductor chip having a small space and a small size and a method of manufacturing the same.

2. Description of the Related Art

Electronic devices and information devices, which have high performance, high speed, and a large memory capacity, are the current trend. In accordance with the above-mentioned trend, the integration of integrated circuits for semiconductor memories is increased, sizes of semiconductor chips are increased, and many input and output pins are required. In addition, the demand for semiconductor chip packages having reduced weight, thickness, length, and size as well as many pins is rapidly growing, since electronic devices and information devices are reducing in size and weight. However, if a small semiconductor device has many input and output pins, a lead pitch of a semiconductor package gets extremely small. Accordingly, the lead of the package can be easily damaged due to outside impact, performance of the chip is reduced due to electric parasitic variables, and the package needs to be handled carefully.

Therefore, currently, a ball grid array package and a chip scale package where semiconductor chips are packaged in a very small space are provided, and the packages are mounted by using various types of electric bonding processes such as wire bonding, TAB (tape automated bonding), and flip chip bonding.

The ball grid array (BGA) package is a novel type package, in which disadvantageous characteristics caused by inductive elements coming from a long lead of a pin grid array (PGA) are prevented, and, additionally, efficiency of input and output pins can also be ensured. The ball grid array (BGA) package is thereby useful for devices requiring many leads.

With respect to the ball grid array package, a printed circuit board (PCB) is used instead of a conventional lead frame so that trimming/forming and plating processes can be replaced by a single ball placement process during an assembling process.

FIG. 1 is a sectional view of a semiconductor package illustrating a ball grid array package using a conventional wire bonding process. A semiconductor chip 12 where desired circuit elements are provided by using a wafer processor is mounted on a substrate 11 such as a PCB where wiring lines (not shown) made of copper and so on are formed. A plurality of pads 13 are formed on a predetermined portion on the substrate 11 so as to be spaced apart from the semiconductor chip 12 by predetermined intervals. A plurality of bump electrodes 14 are disposed with predetermined intervals on a predetermined portion of the semiconductor chip 12. The pads 13 and the bump electrodes 14 are electrically connected through bonding wires 15. In addition, a sealing resin 16 such as an epoxy molding compound (EMC) is filled in order to protect the semiconductor chip 12 and the bonding wires 15 from an outside environment. Furthermore, a plurality of holes 17 is formed in the substrate 11 and filled with a conductive substance. Solder balls 18 are electrically connected to the holes 17 which are filled with the conductive substance. The solder balls 18 are electrically connected to the semiconductor chip 12 through the holes 17 which are filled with the conductive substance. Accordingly, external electric signals may be input into the semiconductor chip 12, or data transmitted from the semiconductor chip 12 may be output to the outside through the solder balls 18. Particularly, by using the solder balls 18 as power voltage terminals or ground power terminals, inductance and resistance can be reduced due to the shorter electric connection distance. The solder balls 18 function to emit heat generated from the semiconductor chip 12 to the outside as well.

However, in the ball grid array package using the wire bonding, product reliability is poor, and it is difficult to perform mounting due to warpage of products or poor coplanarity of the solder balls. As a result, the ball grid array package is not desirable for high-speed, high-performance, and high-density mounting.

Meanwhile, the flip chip bonding is the most preferred for the high-speed, high-performance, and high-density mounting, and is used to directly connect electrodes disposed on the semiconductor chip to the bonding terminal of the substrate.

FIG. 2 is a sectional view of a semiconductor package illustrating a ball grid array package using a conventional flip chip bonding process.

With reference to FIG. 2, a semiconductor chip 22 is mounted on a substrate 21 that includes a PCB where wiring lines (not shown) made of copper, etc., are provided. The semiconductor chip 22 is electrically connected to the substrate 21 through a plurality of bump electrodes 23 that are disposed with predetermined intervals. In addition, an epoxy resin fills a space that is formed by the bump electrodes 23 between the substrate 21 and the semiconductor chip 22, and thereby forms an underfill layer 24. As such, the substrate 21 and the semiconductor chip 22 are attached to each other not to be separated. The underfill layer 24 is also formed at lateral surfaces of the bump electrodes 23. In addition, a sealing resin 25 such as an epoxy molding compound (EMC) is filled in order to protect the semiconductor chip 22 from an outside environment. Furthermore, a plurality of holes 26 is formed in the substrate 21 and filled with a conductive substance. Solder balls 27 are electrically connected to the holes 26 which are filled with the conductive substance.

In the flip chip bonding process, since a space corresponding to a conventional wire bonding process can be saved, it is possible to manufacture a small package. Hence, the flip chip bonding process is mostly applied to high end products requiring high performance, and to products requiring a minimum wiring line width to minimize the package cost.

However, the flip chip bonding process needs to be improved because of difficulties and limitations during the underfill process (epoxy underfill), which is performed to fill the space between the substrate and the semiconductor chip after the semiconductor chip is attached to the substrate where bump electrodes are formed. In addition, even though a snap cure material is used during the underfill process, there is a limitation to reduce the process and curing times. Furthermore, since a molding compound process is performed on the substrate, there is a limitation in scaling to an initial individual element size. Additionally, since hole and solder ball processes are performed on a rear surface of the substrate in order to maintain a chip scale package (CSP) and connect electric wiring lines, the entire process is complicated.

In order to improve the ball grid array package, a wafer level package is increasingly used. Unlike a conventional process where each chip is packaged after being divided from a wafer, the wafer level package is a semiconductor package process where assembling is performed on a wafer before the individual chips are divided. That is, in the conventional package process, the chips are divided from the wafer after wafer processes are finished, attached to a small substrate, connected to wiring lines, and then molded. However, in the wafer level package process, as shown in FIG. 3A, a rear surface of a semiconductor substrate 31 on which a predetermined element structure is formed is ground beforehand. A passivation film 33 is provided on an entire upper surface of the semiconductor substrate 31. A portion of the passivation film 33 corresponding to a region where bump electrodes 32 are to be formed is removed, and then the bump electrodes 32 are formed on that portion of the passivation film. The rear surface of the semiconductor substrate 31 is molded with plastics. And the semiconductor substrate 31 is sawed into predetermined pieces to manufacture semiconductor chips 30 shown in FIG. 3B.

In the wafer level package process, semiconductor assembling steps such as connection of wiring lines, plastic packaging, and so on can be omitted. Moreover, it is not necessary to use plastics, circuit substrates, and wires that were typically used during the assembly of semiconductors, resulting in significant cost reduction. Particularly, because a package having the same size as a chip can be manufactured, the size of the package may be reduced further compared to the conventional chip scale package (CSP) process that has been used to reduce the size of semiconductor devices. Thereby, manufacturing a memory module having a large capacity becomes easier, since more chips may be mounted onto per unit area of the memory module.

However, the passivation film 33 is not provided on a lateral surface of each semiconductor chip 30 after sawing the wafer into individual semiconductor chips. As such, the lateral surface (A) of the semiconductor chip 30 is exposed, and damages to the lateral surface (A) of the semiconductor chip 30 can hardly be prevented.

### SUMMARY OF THE INVENTION

The present invention is to provide a novel semiconductor CSP package that is capable of avoiding difficulties in performing an epoxy underfill process used in a conventional flip chip bonding, and complexity and high cost resulting from a molding compound process and a solder ball process; and a method of manufacturing the same.

Furthermore, the present invention is to provide a semiconductor package that is capable of preventing damages to a lateral surface of a semiconductor chip caused by an absence of a passivation film on the lateral surface of the semiconductor chip in a conventional wafer level package (WLP); and a method of manufacturing the same.

According to an embodiment of the present invention, a semiconductor package includes: a semiconductor chip that includes metal pads provided on a predetermined area of an upper side of a semiconductor substrate, where element structures used to manufacture a semiconductor element are formed, and bump electrodes connected to the metal pads; and a passivation film that is provided on an entire surface of the semiconductor chip other than upper surface of the bump electrodes.

The semiconductor package may further include a complex insulating protection film provided on the semiconductor substrate between the metal pads, and metal wiring lines formed in the complex insulating protection film.

The passivation film may be provided on upper, bottom and lateral surfaces of the semiconductor chip other than the upper surfaces of the bump electrodes.

According to the embodiment of the invention, a method of manufacturing a semiconductor package includes: forming metal pads on a predetermined area of an upper side of a semiconductor substrate on which an element structure used to manufacture a semiconductor element is provided; forming a complex insulating protection film on the entire semiconductor substrate followed by exposing the metal pads, forming bump electrodes to be connected to the metal pads; sawing the semiconductor substrate to form semiconductor chips; forming a passivation film on the resulting structure including an upper surface, a bottom surface, and a lateral surface of each of the semiconductor chips after upper surfaces of the bump electrodes are taped with a predetermined substance; and removing the taping substance from the upper surfaces of the bump electrodes.

According to another embodiment of the invention, a method of manufacturing a semiconductor package includes: forming metal pads on a predetermined area of an upper side of a semiconductor substrate on which an element structure used to manufacture a semiconductor element is provided; forming a first complex insulating protection film on the entire semiconductor substrate followed by exposing the metal pads; forming metal wiring lines on a predetermined area of an upper side of the first complex insulating protection film so as to be connected to the metal pads; forming a second complex insulating protection film on the entire semiconductor substrate followed by exposing the metal wiring lines; forming bump electrodes to be connected to the metal wiring lines; sawing the semiconductor substrate to form semiconductor chips; forming a passivation film on the resulting structure including an upper surface, a bottom surface, and a lateral surface of each of the semiconductor chips after upper surfaces of the bump electrodes are taped with a predetermined substance; and removing the taping substance from the upper surfaces of the bump electrodes.

The method may further include forming a diffusion prevention film before the bump electrodes are formed. And the diffusion prevention film may be formed of one or more selected from a laminate of tantalum nitride (TaN) and tantalum (Ta), a laminate of titanium nitride (TiN) and titanium (Ti), a single layer of titanium tungsten (TiW), a laminate of gold (Au) and titanium tungsten (TiW), and a laminate of copper (Cu) and titanium tungsten (TiW).

The bump electrodes may be formed of: any one selected from a single layer of tin (Sn), a laminate of copper (Cu) and tin (Sn), a laminate of copper (Cu) and a metal alloy, a laminate of chromium (Cr), a metal alloy, and copper (Cu), a laminate of titanium tungsten (TiW) and copper (Cu), and a laminate of a metal alloy, copper (Cu), and tin (Sn); or a metal alloy containing one or more selected from metal elements such as copper (Cu), tin (Sn), lead (Pb), chromium (Cr), titanium (Ti), titanium tungsten (TiW), nickel (Ni), and vanadium (V) and so forth. The bump electrodes may be formed by using an electroplating process or a screen printing process. Furthermore, the method may further include performing a reflow process after the electroplating process or the screen printing process is performed.

The passivation film may be made of: a polymer-based substance including polymide or parylene; or an insulating substance which includes an organic or an inorganic substance having high moisture resistance, and thermal conductivity. A thickness of the passivation film may be controlled according to an operation condition of each of the semiconductor chips, and the passivation film may be formed by using a plasma discharging process, a vacuum deposition process, or a wet adsorption process.

Meanwhile, the predetermined substance used to tape the upper surfaces of the bump electrodes may include a cover tape.

### BRIEF DESCRIPTION OF THE DRAWINGS

The above and other features and advantages of the present invention will become more apparent by describing in detail preferred embodiments thereof with reference to the attached drawings in which:

FIG. 1 is a sectional view of a ball grid array package using a conventional wire bonding process;

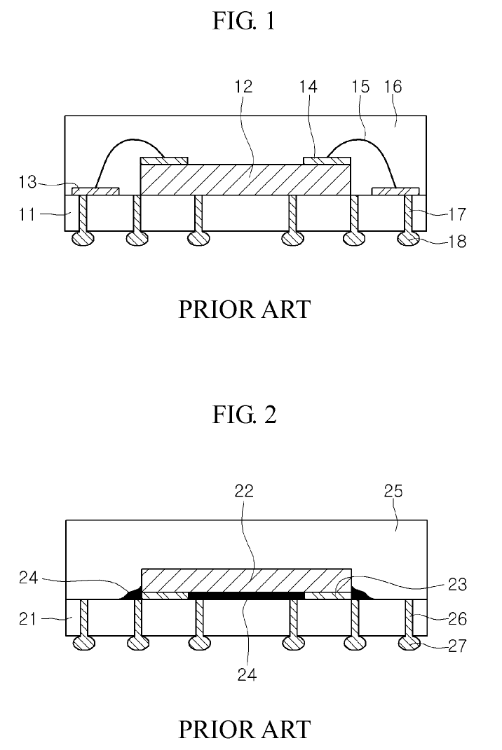

FIG. 2 is a sectional view of a ball grid array package using a conventional flip chip bonding process;

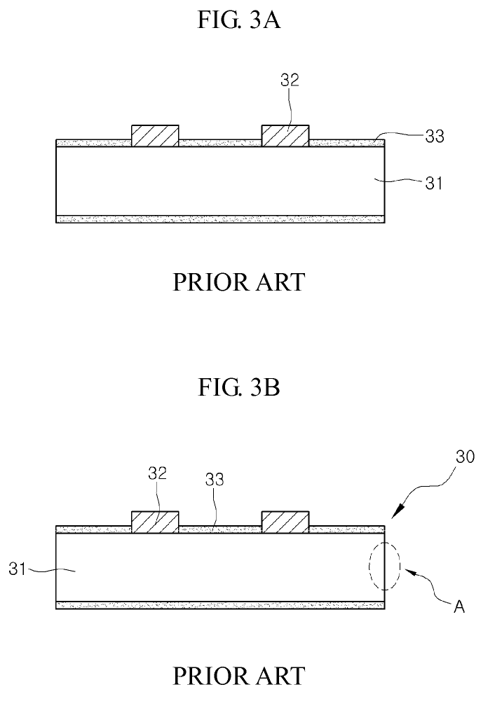

FIG. 3 is a sectional view of a conventional wafer level package; and

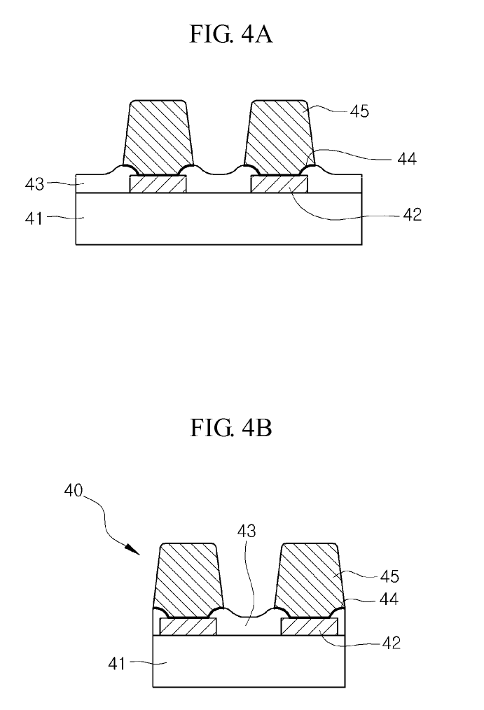

FIGS. 4A to 4D are sectional views illustrating the stepwise manufacturing of a semiconductor package according to an embodiment of the invention.

### DESCRIPTION OF THE PREFERRED EMBODIMENTS

Embodiments of the invention shall be described in detail with reference to the accompanying drawings hereinafter.

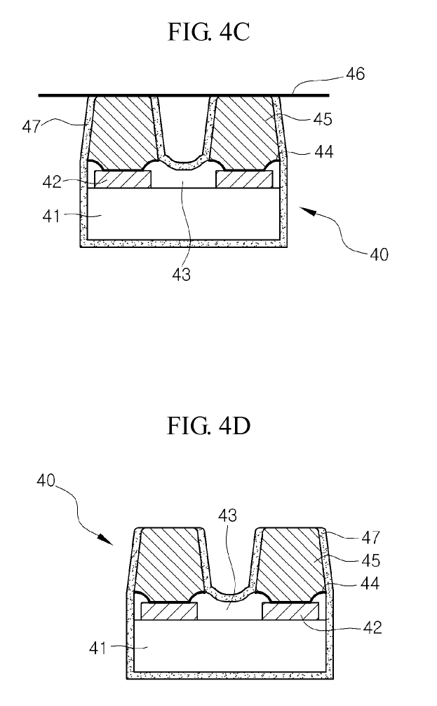

FIGS. 4A to 4D are sectional views illustrating the stepwise manufacturing of a semiconductor package according to an embodiment of the invention.

With reference to FIG. 4A, metal pads 42 are provided on a semiconductor substrate 41 on which a predetermined element structure to manufacture a semiconductor element is formed. A plurality of the metal pads 42 are made of, for example, aluminum (Al) or copper (Cu), and spaced apart by predetermined intervals. Furthermore, a complex insulating protection film 43 is provided on the entire structure, and then selectively etched away so as to expose a predetermined portion of the metal pads 42. The complex insulating protection film 43 may be formed of a complex multilayered film of an oxide film and a nitride film. After a diffusion prevention film 44 is provided on the entire structure, a portion of the diffusion prevention film 44 except for areas on which bump electrodes are to be formed is removed. The diffusion prevention film 44 is provided in order to prevent a reaction between the metal pads 42 and the bump electrodes to be formed. The diffusion prevention film 44 is formed of one or more selected from a laminate of tantalum nitride (TaN) and tantalum (Ta), a laminate of titanium nitride (TiN) and titanium (Ti), a layer of titanium tungsten (TiW), a laminate of gold (Au) and titanium tungsten (TiW), and a laminate of copper (Cu) and titanium tungsten (TiW). In addition, bump electrodes 45 are formed by using a metal layer so as to be electrically connected to the metal pads 42. The bump electrodes 45 are selected from a single layer of tin (Sn); a laminate of copper (Cu) and tin (Sn); a laminate of copper (Cu) and a metal alloy (alloy of tin (Sn) and silver (Ag); a laminate of chromium (Cr), a metal alloy (alloy of chromium (Cr) and copper (Cu)), and copper (Cu); a laminate of titanium tungsten (TiW) and copper (Cu); and a laminate of a metal alloy (alloy of nickel (Ni) and vanadium (V)), copper (Cu), and tin (Sn). Otherwise, the bump electrode 45 are made of a metal alloy including one or more selected from metal elements such as copper (Cu), tin (Sn), lead (Pb), chromium (Cr), titanium (Ti), titanium tungsten (TiW), nickel (Ni), vanadium (V) and so forth. In this connection, a reflow process is performed at a high temperature of 250° C. or more for improving adhesion strength between substances constituting the bump electrodes 45 and for a bumping process. For example, after an electroplating process to form copper, and a screen printing process to form metal substance provided on copper are performed, the reflow process is performed at a high temperature of 250° C. or more.

With reference to FIG. 4B, the semiconductor substrate 41 on which the pad electrodes 42, the complex insulating protection films 43, the diffusion prevention films 44, and the bump electrodes 45 are formed is sawed so that the bump electrodes 45 may not be damaged. Thereby, individual semiconductor chips 40 are created.

With reference to FIG. 4C, upper surfaces of the bump electrodes 45 of each semiconductor chip 40 are taped with a cover tape 46. In addition, a passivation film 47 is made of a polymer-based substance including polymide or parylene at a room temperature of 30° C. or more. Alternatively, the passivation film 45 may be made of an insulating substance having high dielectric constant, moisture resistance, and thermal conductivity. Thereby, the passivation film 47 is provided on the entire structure other than the upper surfaces of the bump electrodes 45 that are taped with the cover tape 46. Furthermore, moisture resistance and endurance to physical damage of the semiconductor chip 40 are improved. In connection with this, the thickness of the passivation film is controlled according to an operation condition of each of the elements. For example, when an operation voltage is less than 2200 V, the passivation film 47 is formed with a thickness of 50 μm or less. Meanwhile, when the passivation film 47 is provided by using plasma discharging, the passivation film is formed at a low temperature of 150° C. or less. The passivation film 47 may be formed by vacuum deposition processes such as evaporation, chemical vapor deposition (CVD), or plasma enhanced CVD, wherein raw materials constituting the passivation film are vaporized (10E-2 Torr or less) and deposited in a vacuum. Alternatively, the passivation film 47 may be formed by methods including wet adsorption process such as a sol-gel process. Thereby, the passivation film can be formed on a front surface, a rear surface and even on a lateral surface of the small semiconductor chip so that the surfaces can thoroughly be protected from an outside environment.

With reference to FIG. 4D, the cover tape 46 is removed after the passivation film 47 is formed. Thereby, a chip scale package (CSP), where the passivation film 47 is provided on the entire surfaces of the semiconductor chip 40 except the upper surfaces of the bump electrodes 45, is manufactured.

Meanwhile, in the above-mentioned embodiment, a description is specifically given for an exemplification where the metal pads are connected directly to the bump electrodes. However, the invention is not limited thereto, but may be applied to various types of package processes. In another embodiment of the invention, after metal wiring lines are formed to be connected to metal pads, bump electrodes are provided to be connected to the metal wiring lines. A description thereof will be given.

A plurality of metal pads is provided on an upper surface of a semiconductor substrate on which formation of a predetermined structure for elements is completed. After a first complex insulating protection film is formed thereon, a predetermined area of the first complex insulating protection film is removed so as to expose the metal pads. In addition, a metal substance such as aluminum (Al), copper (Cu), titanium (Ti), tantalum (Ta), titanium nitride (TiN), tantalum nitride (TaN), or titanium tungsten (TiW) is applied thereonto, and then selectively etched to form metal wiring lines. Next, after a second complex insulating protection film is provided thereon, the second complex insulating protection film is removed from an area on which the bump electrodes are to be formed so as to expose a predetermined portion of the metal wiring lines. After a diffusion prevention film is provided thereon, a predetermined area of the diffusion prevention film is etched so that the diffusion prevention film remains only on the area on which the bump electrodes are to be formed. Furthermore, the bump electrodes are provided to be connected to the metal wiring lines through the diffusion prevention film. After the semiconductor substrate including the resulting structure is sawed to form individual semiconductor chips, upper surfaces of the bump electrodes are covered with a cover tape or any other means. And then a passivation film is provided on the entire structure including an upper surface, a bottom surface, and a lateral surface of the semiconductor chip. Subsequently, the cover tape is removed from the upper surfaces of the bump electrodes.

As described above, in the present invention, after an upper surface of a bump electrode is taped with a cover tape, a passivation film can be formed on an entire surface of a semiconductor chip, which has a small space and small size, including even a lateral surface thereof. Therefore, it is possible to avoid difficulties in performing an epoxy underfill process used in a conventional flip chip bonding, and complexity and high cost resulting from the use of a molding compound process and a solder ball process. It is also possible to prevent damages to the lateral surface of the semiconductor chip due to an absence of the passivation film on the lateral surface of the semiconductor chip in a conventional wafer level package.

In addition, the passivation film is formed of a polymer-based substance including polymide or parylene; or an insulating substance having high dielectric constant, moisture resistance, and thermal conductivity. Further, the passivation film is formed at around room temperature of 30° C. or more, which allows a stable low temperature. Accordingly, reliability of elements is ensured, the scope of the material selection is broadened, and cost reduction is also possible.

Meanwhile, since the thickness of the passivation film can be controlled according to the level of external operation voltage and desired protection voltage, it is possible to perform a package process where a minimum size and high reliability can be ensured at minimum cost.

What is claimed is:

1. A method of manufacturing a semiconductor package comprising:
forming metal pads on a predetermined area of an upper side of a semiconductor substrate on which an element structure used to manufacture a semiconductor element is provided;
forming a complex insulating protection film on the entire semiconductor substrate and exposing the metal pads;
forming bump electrodes to be connected to the metal pads;
sawing the semiconductor substrate to form semiconductor chips;
forming a passivation film on the resulting structure including an upper surface, a bottom surface, and a lateral surface of each of the semiconductor chips after upper surfaces of the bump electrodes are taped with a predetermined substance; and
removing the taping substance from the upper surfaces of the bump electrodes.

2. The method of claim 1, further comprising forming a diffusion prevention film before the bump electrodes are formed.

3. The method of claim 2, wherein the diffusion prevention film is formed of one or more selected from a laminate of tantalum nitride (TaN) and tantalum (Ta), a laminate of titanium nitride (TiN) and titanium (Ti), a single layer of titanium tungsten (TiW), a laminate of gold (Au) and titanium tungsten (TiW), and a laminate of copper (Cu) and titanium tungsten (TiW).

4. The method of claim 1, wherein the bump electrodes are formed of any one selected from a single layer of tin (Sn), a laminate of copper (Cu) and tin (Sn), a laminate of copper (Cu) and a metal alloy, a laminate of chromium (Cr), a metal alloy, and copper (Cu), a laminate of titanium tungsten (TiW) and copper (Cu), and a laminate of a metal alloy, copper (Cu), and tin (Sn); or a metal alloy containing one or more selected from metal elements such as copper (Cu), tin (Sn), lead (Pb), chromium (Cr), titanium (Ti), titanium tungsten (TiW), nickel (Ni), vanadium (V) and so forth.

5. The method of claim 1, wherein the bump electrodes are formed by using an electroplating process and/or a screen printing process.

6. The method of claim 5, further comprising performing a reflow process after the electroplating process and/or the screen printing process are performed.

7. The method of claim 1, wherein the passivation film is made of a polymer-based substance including polymide or parylene or an insulating substance which includes an organic or an inorganic substance having high moisture resistance, and thermal conductivity.

8. The method of claim 1, wherein a thickness of the passivation film is controlled according to an operation condition of each of the semiconductor chips.

9. The method of claim 1, wherein the passivation film is formed by using a plasma discharging process, a vacuum deposition process or a wet adsorption process.

10. The method of claim 1, wherein the predetermined substance used to tape the upper surfaces of the bump electrodes includes a cover tape.

11. A method of manufacturing a semiconductor package comprising:
forming metal pads on a predetermined area of an upper side of a semiconductor substrate on which an element structure used to manufacture a semiconductor element is provided;
forming a first complex insulating protection film on the entire semiconductor substrate and exposing the metal pads;
forming metal wiring lines on a predetermined area of an upper side of the first complex insulating protection film so as to be connected to the metal pads;
forming a second complex insulating protection film on the entire semiconductor substrate and exposing the metal wiring lines;
forming bump electrodes to be connected to the metal wiring lines;
sawing the semiconductor substrate to form semiconductor chips;
forming a passivation film on the resulting structure including an upper surface, a bottom surface, and a lateral surface of each of the semiconductor chips after upper surfaces of the bump electrodes are taped with a predetermined substance; and
removing the taping substance from the upper surfaces of the bump electrodes.

12. The method of claim 11, further comprising forming a diffusion prevention film before the bump electrodes are formed.

13. The method of claim 12, wherein the diffusion prevention film is formed of one or more selected from a laminate of tantalum nitride (TaN) and tantalum (Ta), a laminate of titanium nitride (TiN) and titanium (Ti), a single layer of titanium tungsten (TiW), a laminate of gold (Au) and titanium tungsten (TiW), and a laminate of copper (Cu) and titanium tungsten (TiW).

14. The method of claim 11, wherein the bump electrodes are formed of any one selected from a single layer of tin (Sn), a laminate of copper (Cu) and tin (Sn), a laminate of copper (Cu) and a metal alloy, a laminate of chromium (Cr), a metal alloy, and copper(Cu), a laminate of titanium tungsten (TiW) and copper (Cu), and a laminate of a metal alloy, copper (Cu), and tin (Sn); or a metal alloy containing one or more selected from metal elements such as copper (Cu), tin (Sn), lead (Pb), chromium (Cr), titanium (Ti), titanium tungsten (TiW), nickel (Ni), vanadium (V) and so forth.

15. The method of claim 11, wherein the bump electrodes are formed by using an electroplating process and/or a screen printing process.

16. The method of claim 15, further comprising performing a reflow process after the electroplating process and/or the screen printing process is performed.

17. The method of claim 11, wherein the passivation film is made of a polymer-based substance including polymide or parylene or an insulating substance which includes an organic or an inorganic substance having high moisture resistance and thermal conductivity.

18. The method of claim 11, wherein a thickness of the passivation film is controlled according to an operation condition of each of the semiconductor chips.

19. The method of claim 11, wherein the passivation film is formed by using a plasma discharging process, a vacuum deposition process or a wet adsorption process.

20. The method of claim 11, wherein the predetermined substance used to tape the upper surfaces of the bump electrodes includes a cover tape.
